(19) United States
(12) Patent Application Publication
(10) Pub. No.: US 2020/0068748 A1
(43) Pub. Date: Feb. 27, 2020

(54) DISCRETE COOLING CHANNEL FOR POWER ELECTRONICS

(71) Applicant: Kostal of America, Inc., Troy, MI (US)

(72) Inventors: Steven R. Hoskins, Walled Lake, MI (US); Kenneth S. Koscielniak, Farmington Hills, MI (US)

(73) Assignee: Kostal of America, Inc., Troy, MI (US)

(21) Appl. No.: 16/535,918

(22) Filed: Aug. 8, 2019

Related U.S. Application Data
(60) Provisional application No. 62/722,261, filed on Aug. 24, 2018.

(51) Int. Cl. H05K 7/20; H01L 23/473

(52) U.S. Cl. CPC H05K 7/20927; H05K 7/20254; H01L 23/473; H05K 7/20272

(57) ABSTRACT

A liquid cooled power electronic device includes a unitary cooling body defining a fluid passageway; a separately fabricated main housing having a recess for receiving the cooling body; and a circuit substrate having an electronic component in conductive thermal contact with the cooling body, wherein the cooling body is retained within the recess between the main housing and the circuit substrate. This arrangement has one or more advantages relating to improved leak testing, improved thermal performance, and reduced scrap.

### CROSS-REFERENCE TO RELATED APPLICATION

This application claims priority to provisional Application No. 62/722,261, filed Aug. 24, 2018, which is incorporated herein by reference in its entirety.

### FIELD OF THE DISCLOSURE

This disclosure relates to liquid cooled power electronics.

### BACKGROUND OF THE DISCLOSURE

High power electronics devices used in various home electronics, industrial drives, telecommunications and electric grid applications require advanced cooling techniques that are not possible with conventional air-cooled systems. In such applications, liquid cooling provides a practical solution. However, liquid cooling of power electronics modules presents significant challenges. These challenges include sealing against leaks, moving the cooling fluid to closer proximity of heat generating components, and generating turbulent flow of the cooling fluid to improve thermal performance of the cooling system. Another significant challenge of current liquid cooling system designs for high power electronics devices is leak testing can only take place after assembly, leading to significant scrap costs when leaks are detected.

### SUMMARY OF THE DISCLOSURE

The disclosed liquid cooled power electronic devices overcome one or more of the above-mentioned problems associated with known cooling systems.

The disclosed devices include a unitary cooling body defining a fluid passageway for a cooling medium between an inlet and an outlet; a separately fabricated main housing having a recess for receiving the cooling body; and a circuit substrate having an electronic component that is in thermal contract with the cooling body, with the cooling body retained within the recess between the main housing and the circuit substrate.

In certain aspects of this disclosure, the cooling body is fabricated from a single homogeneous mass of material using a hydroforming technique that inherently tests for leaks.

In certain other aspects of this disclosure, walls of the cooling body are provided with surface deformations to introduce or enhance turbulence into the flow of the cooling medium passing through the cooling body.

These and other advantages will be more fully appreciated in view of the following detailed descriptions.

### BRIEF DESCRIPTION OF THE DRAWINGS

FIG. 1 is an exploded perspective view showing the various components and assembly of the liquid cooled power electronic devices disclosed herein.

FIG. 2 is a partial cross-sectional view of the device shown in FIG. 1.

FIG. 3 is an enlarged perspective view of the cooling body used in the liquid cooled power electronic device of FIG. 1.

### DETAILED DESCRIPTION OF THE PREFERRED EMBODIMENTS

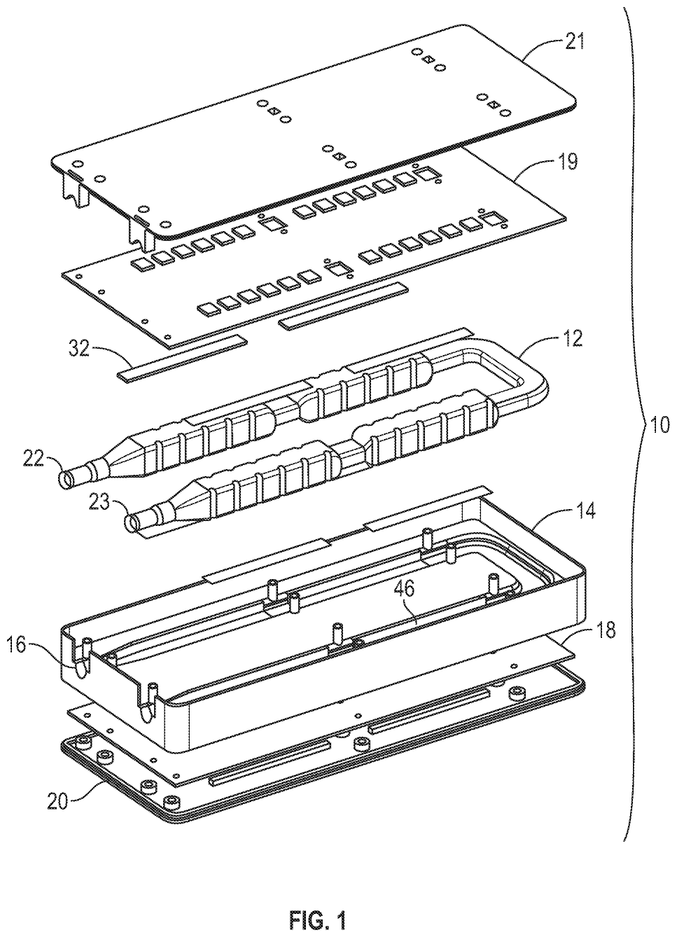

A preferred embodiment of the disclosed liquid cooled power electronic device is shown in FIG. 1. The device 10 includes a unitary cooling body 12 through which a cooling medium is circulated for the purpose of absorbing heat from heat-generating electrical components and carrying the heat away from the device to maintain a suitable operating temperature that promotes reliable operation for an extended service life.

Device 10 also includes a framework or main housing 14 onto which other elements of the device are attached. Main housing 14 includes a recess 16 configured to receive cooling body 12, and at least one circuit substrate 18 having an active electronic component in thermal contact with a surface of cooling body 12. In the illustrated embodiment of FIG. 1, device 10 includes two circuit substrates 18, 19, each of which includes an active electronic component in thermal contact with one of two opposite sides of cooling body 12. Main housing 14 can be configured to define a window or opening 46 through which an active electronic component or circuit substrate 18 can contact cooling body 12. Circuit substrates 18 and 19 can be attached to main housing 14 using an adhesive material or using mechanical fasteners, such as clips or screws (not shown).

If desired, the assembled device can be enclosed using covers 20 and 21. Covers 20, 21 can be secured to main housing 14 with adhesives, mechanical fasteners, or welds (e.g., friction welds, ultrasonic welds, etc.).

The unitary cooling body 12 can be formed or fabricated in a single operation to produce a one-piece body that is preferably seamless, but may have parting lines. In particular, cooling body 12 is fabricated separately from main housing 14. This allows cooling body 12 to be fabricated from a different material than that of main housing 14. This can have any advantage of using a material with a higher thermal conductivity for the cooling body 12 than that of the main housing 14, while using a material having a lower cost, greater strength and/or lighter weight for the main housing 14 than that of the cooling body 12.

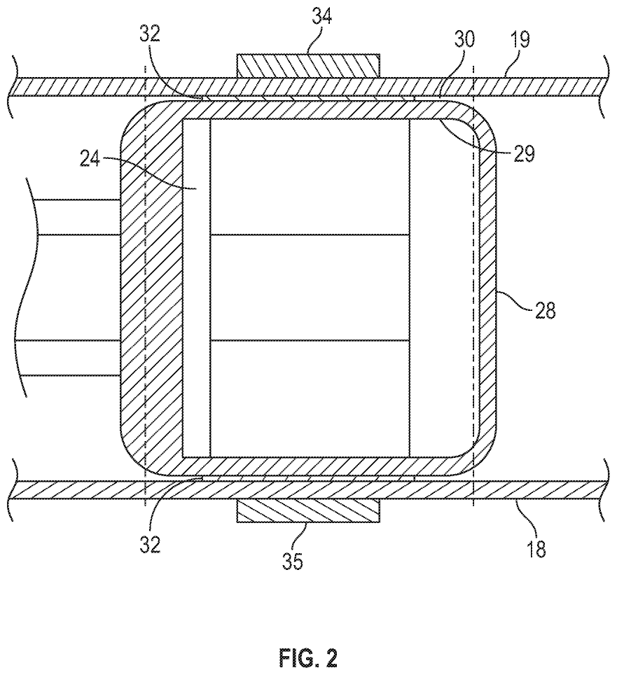

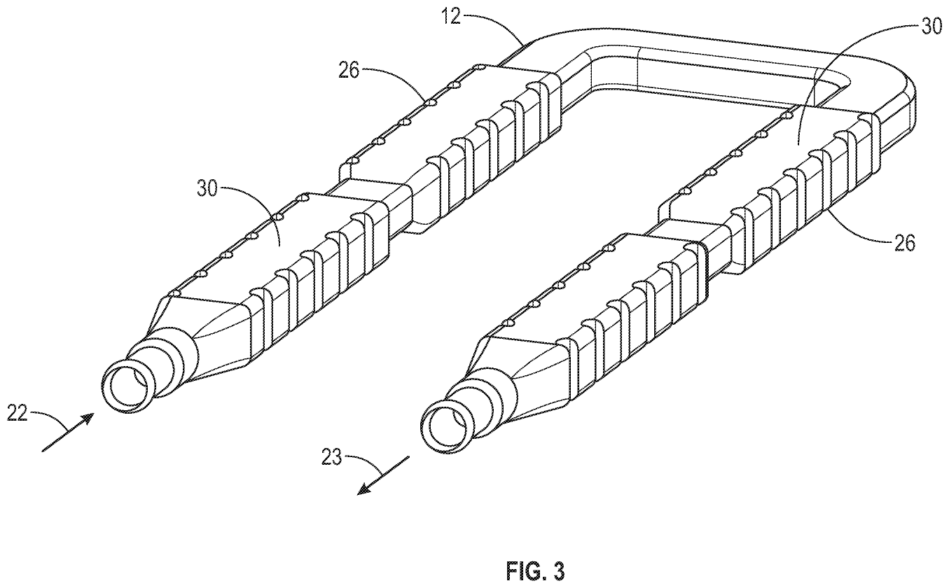

Cooling body 12 includes a fluid inlet 22, a fluid outlet 23, and a fluid passageway 24 (FIGS. 2 and 3) between fluid inlet 22 and fluid outlet 23. Cooling body 12 can be fabricated using a hydroforming process that inherently involves an initial leak and pressure test. Suitable materials include ductile metals, such as aluminum, brass, low alloy steel, and stainless steel. Surface deformations 26 (e.g., convex or concave dimples, ridges, grooves or bumps) can be provided along the walls of the cooling body 12 to introduce or increase turbulence to the flow of the cooling medium passing through passageway 24.

Cooling body 12 includes an external surface 28 for absorbing heat from its surroundings, and an internal surface 29 for transferring heat to a fluid flowing through passageway 24. More specifically, in a particular embodiment shown in FIG. 2, a recess 30 is formed on the external surface 28 of cooling body 12 to retain thermal interface material 32 (e.g., thermal grease) that facilitates or promotes conductive heat transfer from an active electronic component 34, 35 mounted on a circuit substrate 18, 19 to cooling body 12.

Circuit substrates 18 and 19 can comprise a thin slice of material that serves as a rigid foundation (e.g., circuit board) upon which a solid state electronic device is fabricated and/or assembled. Alternatively, circuit substrates 18 and 19 can be flexible. Various active electronic components 34, 35 can be fabricated on or mounted to the circuit substrates 18, 19. Examples of components 34, 35 include MOSFETs (metal-oxide-semiconductor field effect transistors), GTOs (gate turn-off thyristors), IGBTs (insulated-gate bipolar transistors), IGCTs (integrated gate-commutated thyristors), as well as other power semiconductor components.

The above description is intended to be illustrative, not restrictive. The scope of the invention should be determined with reference to the appended claims along with the full scope of equivalents. It is anticipated and intended that future developments will occur in the art, and that the disclosed devices, kits and methods will be incorporated into such future embodiments. Thus, the invention is capable of modification and variation and is limited only by the following claims.

What is claimed is:

1. A liquid cooled power electronic device, comprising:
a unitary cooling body defining a fluid inlet, a fluid outlet, a fluid passageway between the fluid inlet and the fluid outlet, the cooling body having external surfaces for absorbing heat from surroundings of the cooling body and internal surfaces for transferring heat to a fluid flowing through the passageway, wherein deformations are provided along walls of the cooling body to introduce or increase turbulence to a cooling medium passing through the cooling body;
a main housing having a recess configured to receive the cooling body; and
a first circuit substrate having a first active electronic component in thermal contact with the external surface of a first side of the cooling body, wherein the cooling body is retained within the recess between the main housing and the circuit substrate.

2. The device of claim 1, further comprising a second circuit substrate having a second active electronic component in thermal contact with the external surface of the cooling body on a second side of the cooling body opposite of the first side of the cooling body.

3. The device of claim 1, further comprising a cover to enclose the cooling body and first circuit substrate within the main housing.

4. The device of claim 2, further comprising a first cover to enclose the cooling body and first circuit substrate within the main housing, and a second cover to enclose the second circuit substrate within the main housing.

5. The device of claim 1, wherein the cooling body is fabricated from a material that has a higher thermal conductivity than the material used to fabricate the main housing.

6. The device of claim 1, wherein the main housing is fabricated from a material having greater strength than the material used to fabricate the cooling body.

7. The device of claim 6, wherein the cooling body is fabricated from a material that has a higher thermal conductivity than the material used to fabricate the main housing.

8. The device of claim 1, wherein the cooling body is fabricated from aluminum.

9. The device of claim 1, wherein the cooling body is fabricated from low alloy steel.

10. The device of claim 1, wherein the cooling body is fabricated from stainless steel.

11. The device of claim 1, wherein a recess is formed on an external surface of the cooling body, and a thermal interface material is disposed in the recess to promote conducive heat transfer from the active electronic component to the cooling body.

12. A method of fabricating a liquid cooled power electronic device, comprising:
hydroforming a unitary cooling body defining a fluid inlet, a fluid outlet, a fluid passageway between the fluid inlet and the fluid outlet, the cooling body having external surfaces for absorbing heat from surroundings of the cooling body and internal surfaces for transferring heat to a fluid flowing through the passageway, wherein deformations are provided along walls of the cooling body to introduce or increase turbulence to a cooling medium passing through the cooling body;
positioning the hydroformed unitary cooling body in a recess of main housing configured to receive the cooling body; and
positioning a first circuit substrate having a first active electronic component in thermal contact with the external surface of a first side of the cooling body, wherein the cooling body is retained within the recess between the main housing and the circuit substrate.

13. The device of claim 12, wherein the cooling body is fabricated from a material that has a higher thermal conductivity than the material used to fabricate the main housing.

14. The device of claim 12, wherein the main housing is fabricated from a material having greater strength than the material used to fabricate the cooling body.

15. The device of claim 14, wherein the cooling body is fabricated from a material that has a higher thermal conductivity than the material used to fabricate the main housing.

16. The device of claim 12, wherein the cooling body is fabricated from aluminum.

17. The device of claim 12, wherein the cooling body is fabricated from low alloy steel.

18. The device of claim 12, wherein the cooling body is fabricated from stainless steel.

19. The device of claim 12, wherein a recess is formed on an external surface of the cooling body, and a thermal interface material is disposed in the recess to promote conducive heat transfer from the active electronic component to the cooling body.
